(19) United States
(12) Patent Application Publication
(10) Pub. No.: US 2013/0199600 A1
(43) Pub. Date: Aug. 8, 2013

(54) ARTICLES, SYSTEMS, AND METHODS RELATING TO THERMAL STABILITY OF NANOSTRUCTURED AND/OR MICROSTRUCTURED MATERIALS

(71) Applicant: Massachusetts Institute of Technology, Cambridge, MA (US)

(72) Inventors: Heon Ju Lee, Newton, MA (US); Stephen P. Bathurst, Lafayette, CA (US); Sang-Gook Kim, Wayland, MA (US); Katherine Marie Smyth, Cambridge, MA (US)

(73) Assignee: Massachusetts Institute of Technology, Cambridge, MA (US)

(21) Appl. No.: 13/683,704

(22) Filed: Nov. 21, 2012

Related U.S. Application Data
(60) Provisional application No. 61/563,396, filed on Nov. 23, 2011.

(51) Int. Cl. H01L 31/04

(52) U.S. Cl. CPC H01L 31/0406
USPC 136/253; 438/57

(57) ABSTRACT

The present invention generally relates to articles, systems, and methods relating to the thermal stability of nanostructured and/or microstructured materials.

### RELATED APPLICATIONS

This application claims priority to U.S. Provisional Patent Application Ser. No. 61/563,396, filed Nov. 23, 2011, and entitled “ARTICLES, SYSTEMS, AND METHODS RELATING TO THERMAL STABILITY OF NANOSTRUCTURED AND/OR MICROSTRUCTURED MATERIALS” to Lee et al., which is incorporated herein by reference in its entirety for all purposes.

### STATEMENT REGARDING FEDERALLY SPONSORED RESEARCH OR DEVELOPMENT

This invention was made with government support under Grant Nos. DE-SC0001299 and DE-FG02-09ER46577 awarded by the Department of Energy. The government has certain rights in this invention.

### FIELD OF THE INVENTION

The present invention generally relates to articles, systems, and methods relating to the thermal stability of nanostructured and/or microstructured materials.

### BACKGROUND OF THE INVENTION

In solar thermal photovoltaics (SPV), solar radiation is absorbed by a material (e.g., a selective absorber) and the heat is effectively trapped due to the low emittance at long wavelengths. This collected heat is then transferred via direct conduction to a second material (e.g., a selective emitter) which emits radiation that is matched to the band gap of a single junction solar cell. A common material choice for selective emitters is single crystalline tungsten. Tungsten has high emissivity in the visible and near-IR range of 0.45 to 0.47 and a low emissivity of 0.1 to 0.2 in the IR region. There are generally no grain growth or recrystallization issues as it is a single crystalline. The material price is also relatively lower than other available choices. However, a single junction solar cell alone generally cannot absorb photons with energy below the band gap but absorb a fraction of the photons with the energy above the band gap. The ability to absorb solar radiation and reemit it in a narrow band aids in eliminating these inefficiencies. Photonic crystals are periodic nanostructures that are designed to affect the motion of photons at certain wavelengths. Thus, long wavelength emissivity may be significantly reduced making it possible to match emission to the band gap of a solar cell.

In general, a higher operating temperature increases the efficiency of thermophotovoltaic systems. As the operating temperature increases, the emitted spectral power density can shift to shorter wavelengths which are closer to the band gaps of most solar cell materials. If this is combined with a photonic crystal, which limits long wavelength emissions further, the emitted photons may be very closely aligned in a specific band gap. This can provide high emissivity in the specific band gap to solar cells. However, challenges exist when employing photonic crystals as the nanostructures generally degrade at the required operating temperatures for the systems/crystals.

There are a number of other systems involving emission and/or absorption of electromagnetic radiation, such as light, that can be adversely affected by temperature changes, including high operating temperatures.

Accordingly, improved articles, systems, and methods are needed for a variety of systems involving absorption and/or emission of electromagnetic radiation for resistance of adverse effects caused by temperature changes and/or high temperature operation.

### SUMMARY OF THE INVENTION

In some embodiments, an article is provided comprising a substrate material comprising at least one nanostructure formed in at least one surface of the substrate material; a filler material formed in the at least one nanostructure; and a first film positioned between the at least one substrate material and the filler material.

In some embodiments, a method of forming an article is provided comprising providing a substrate material comprising at least one nanostructure formed in at least one surface of the substrate material; optionally forming a first film on the surface of the at least one nanostructure; and filling the at least one nanostructure with at least one filler material.

In some embodiments, an article is provided comprising a substrate material comprising a photonic material and at least one nanostructure formed in at least one surface of the substrate; and a filler material formed in the at least one nanostructure.

### BRIEF DESCRIPTION OF THE DRAWINGS

FIG. 1 shows images of nanostructured tungsten surfaces prior to and following exposure to various heating conditions, according to some embodiments.

FIGS. 2 shows images of pre-annealed and non-treated polished nanostructures tungsten substrates prior to and following exposure to various heating conditions, according to some embodiments.

FIG. 3 show an illustrated diagram of a cross-section of an article, according to some embodiments.

FIG. 4 shows SEM images of a substrate having filled or non-filled nanostructures prior to and following exposure to various heating conditions, according to some embodiments.

FIG. 5 shows a graph of depth to radius ratio of filler or non-filled nanostructures in a substrate material with respect to heating time, according to some embodiments.

FIG. 6 shows oxidation of tungsten surface for (a) un-treated sample, (b) TiN coated, and (c) TiN coated and oxygen stuffed, according to some embodiments.

FIG. 7 shows XRD data taken after firing at 1200° C. for 10 and 20 hours, according to some embodiments. FIG. 8(a) shows the analysis of the stress distribution when FSTPC was heated up to 1200° C., according to some embodiments.

FIG. 8(b) shows the scalloped side wall of the silicon trench, according to some embodiments.

FIG. 9 shows a process flow of FSPC for tungsten selective emitters, according to some embodiments.

FIG. 10(a) shows crack-free HfO₂ coating on silicon 2-D photonic crystal after annealing, according to some embodiments.

FIG. 10(b) shows a cross-sectional view of HfO₂ filled 2-D Si-PhC, according to some embodiments.

FIGS. 11(a) and 11(b) show HfO₂ plugging methodology, according to some embodiments.

FIG. 12(a) shows a 2-D silicon photonic crystal, unplugged, according to some embodiments.

FIG. 12(b) shows a crack-free & dense HfO₂ filling, before polishing, according to some embodiments.

FIG. 13 shows the effect of plugging HfO₂ on silicon photonic crystal, according to some embodiments.

FIG. 14 shows a cross-sectional view of thermal degradation of silicon photonic crystal structures and corresponding SEM images of HfO₂ plugged sample, according to some embodiments.

FIG. 15 shows the measured emissivity after 0, 50, and 100 hours of firing test at 400° C. for: (a) silicon photonic crystal without any treatment (coating or plugging) and (b) HfO₂ plugged silicon photonic crystal sample, according to some embodiments.

FIG. 16 shows the oxidation on the tungsten surface after 20 hours of firing at 1200° C., according to some embodiments.

Other aspects, embodiments, and features of the invention will become apparent from the following detailed description when considered in conjunction with the accompanying drawings. The accompanying figures are schematic and are not intended to be drawn to scale. For purposes of clarity, not every component is labeled in every figure, nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### DETAILED DESCRIPTION

The present invention generally relates to articles, systems, and methods relating to the thermal stability of materials involved in absorption and/or emission of electromagnetic radiation, including nanostructured and/or microstructured materials. Nanostructured and/or microstructured materials are used for a variety of applications, including, but no limited to thermophotovoltaic systems. In some cases, the material comprises a selective emitter for use in a photovoltaic system.

Nanostructured and/or microstructured materials are materials comprising a plurality of nanostructures and/or microstructures formed in at least one surface of a substrate material. For example, photonic crystals generally have periodic nanostructures and/or microstructures that are designed to control the motion of photons at certain wavelengths, giving off light radiation at favorable wavelengths to be absorbed by adjacent photovoltaic cells. However, in many cases, the nanostructures and/or microstructures formed in the at least one surface can lose their structural integrity when the material is heated to high temperatures, which are often required and/or necessary for efficient operation of the system. This may lead to disruption of the nanostructures and/or microstructures and cause the shape/size/orientation/order of the nanostructures to fall outside the shape/size/orientation/order tolerances generally necessary for the spectral control of the light radiation. Non-limiting mechanism by which such materials degrade upon application of high temperatures (e.g., >800° C.) include surface chemistry changes (oxidation), grain growth and recrystallization, and diffusion of atoms at the surface.

It should be understood, that while much of the discussion herein focuses on nanostructured materials, this is by no means limiting, and similar methods, systems, and articles comprising microstructures materials may be substituted and/or employed.

The present invention generally relates to methods and articles which relate to improving the thermal stability of the nanostructures (and/or microstructures) formed in at least one surface of a substrate material. In some embodiments, the present invention generally relates to filling at least a portion of the nanostructures (and/or microstructures) with a filler material. Without wishing to be bound by theory, replacing the air in the nanostructures (and/or microstructures) with a filler material can aid in minimizing or eliminating the surface diffusion at high temperatures (e.g., due to negligible second derivative of the curvature).

In some embodiments, the substrate material comprises a photonic material. As used herein, the terms “photonic material” and “photonic crystal” are given their ordinary meaning in the art, and refer to a material that can control the propagation of electromagnetic radiation based on a periodic assembly of domains having different dielectric properties. In some embodiments, the photonic crystals include domains with one or more dimensions of the same order of magnitude as the wavelength(s) of the electromagnetic radiation the photonic crystal is configured to control the propagation of. “Photonic crystal” and “photonic material” are used interchangeably herein, and refer to the same class of materials.

As will be known to those of ordinary skill in the art, a photonic crystal generally has a structure of periodic nanostructures and/or microstructures (e.g., nano-holes and/or micro-holes) which make it possible to tune the emit wavelength. Accordingly, in some embodiments, a photonic material may comprise a plurality of nanostructures formed in at least one surface, thereby forming a 1-dimensional and/or a 2-dimensional photonic crystal (e.g., the photonic material can have, in some cases, 1-dimensional and/or 2-dimensional periodicity). One of ordinary skill in the art would be able to determine the dimensionality of the periodicity of a photonic crystal upon inspection. For example, 1-dimensionally periodic photonic crystals include materials arranged in such a way that a line along a first coordinate direction within the photonic crystal passes through multiple domains while lines along second and third orthogonal coordinate directions, each of the second and third coordinate directions being orthogonal to the first coordinate direction within the photonic crystal, do not pass through multiple domains. In some embodiments, the index of refraction at at least one point within the 1-dimensionally periodic photonic crystal varies along a first coordinate direction and does not substantially vary along second and third orthogonal coordinate directions, each of the second and third coordinate directions being orthogonal to the first coordinate direction. For example, a 1-dimensionally periodic photonic crystal can include two or more materials and/or metamaterials arranged in a stack such that a line along a first coordinate direction passes through multiple layers while lines along second and third coordinate directions (each orthogonal to the first coordinate direction) remain within a single layer.

2-dimensionally periodic photonic crystals include materials arranged in such a way that lines along first and second orthogonal coordinate directions within the photonic crystal pass through multiple domains while a line along a third coordinate direction, orthogonal to the first and second coordinate directions, does not pass through multiple domains. In some embodiments, the index of refraction within the volume of a 2-dimensionally periodic photonic crystal varies along first and second orthogonal coordinate directions, but does not substantially vary along a third coordinate direction orthogonal to the first and second coordinate directions. For example, a 2-dimensionally periodic photonic crystal can include two or more materials arranged such that at least one material forms a series of elongated rods that extend through the thickness of another material.

The substrate material may comprise any suitable material, including, but not limited to, metals (e.g., tungsten (e.g., single-crystal tungsten), tantalum, platinum, palladium, silver, gold, etc.), semiconductors (e.g., silicon, germanium, etc.), or dielectric materials (e.g., titania, zirconia, etc.). In some embodiments, the substrate material comprises a refractory metal (e.g., tungsten, tantalum, molybdenum, rhenium, niobium). In some embodiments, the substrate material comprises tungsten, tantalum, or molybdenum. In some embodiments, the substrate material comprises single crystalline tungsten, tantalum, or molybdenum. In one embodiment, the substrate material comprises tungsten. In one embodiment, the substrate material comprises single crystalline tungsten. In one embodiment, the substrate material is single crystalline tungsten. The substrate material may also be of any suitable thickness, for example, greater than or about 50 micrometers, greater than or about 100 micrometers, greater than or about 200 micrometers, greater than or about 300 micrometers, greater than or about 400 micrometers, greater than or about 500 micrometers, greater than or about 600 micrometers, greater than or about 700 micrometers, greater than or about 800 micrometers, greater than or about 900 micrometers, greater than or about 1 mm, greater than or about 2 mm, greater than or about 3 mm, greater than or about 4 mm, greater than or about 5 mm, greater than or about 6 mm, greater than or about 7 mm, greater than or about 8 mm, greater than or about 9 mm, greater than or about 1 cm, or greater.

The nanostructures formed in at least one surface, or in some cases, one surface, of the substrate material may be of any suitable size and/or shape. In some cases, substantially all or all of the nanostructures have substantially similar sizes and/or shapes. Non-limiting examples of suitable cross-sectional shapes include substantially circular, substantially elliptical, substantially square, and substantially rectangular, substantially triangular. In some embodiments, the nanostructures may be formed in the surface of the substrate as trenches, grooves, or crevices. In some embodiments, the nanostructures may be tapered. For example, the nanostructures may be tapered so that the cross-section of a nanostructure at the surface is narrower than the cross-section of the nanostructure at the bottom of the nanostructure.

The nanostructures may have any suitable aspect ratio (e.g., the ratio of the depth of the nanostructure, as measured substantially perpendicularly to the external surface of the substrate material, to the maximum cross-sectional dimension of the nanostructure, as measured substantially parallel to the external surface of the substrate material). For example, the nanostructures have an aspect ratio of at least about 0.75:1 (i.e., the depth of the nanostructure is at least about 0.75 times the maximum cross-sectional dimension of the nanostructure), at least about 2:1, at least about 5:1, at least about 10:1, between about 0.75:1 and about 10:1, between about 2:1 and about 10:1, or between about 5:1 and about 10:1. In some embodiments, wherein the nanostructures form trenches, grooves, or crevices in the surface, the aspect ratio may be larger, for example, at least 1:20 (e.g., the depth of the nanostructure to the length of the nanostructure), at least 1:25, at least 1:50, at least 1:100, at least 1:200, at least 1:300, at least 1:400, at least 1:500, at least 1:600, at least 1:700, at least 1:800, at least 1:900, at least 1:1000, or greater.

In some embodiments, the average of the cross-sectional diameters (calculated as a number average) of the plurality of nanostructures is between about 10 nm and about 1 microns, between about 100 nm and about 1 microns, or between about 100 nm and about 500 nanometers. In some embodiments, the average of the cross-sectional diameters (calculated as a number average) of the plurality of microstructures is between about 1 micron and about 10 microns, between about 1 micron and about 5 microns, or between about 1 micron and about 2 microns. In some embodiments, the average of the cross-sectional diameters (calculated as a number average) of the plurality of nanostructures and/or microstructures is between about 10 nm and about 10 microns, between about 100 nanometers and about 5 microns, or between about 500 nanometers and about 5 microns. In some embodiments, at least about 50%, at least about 75%, at least about 90%, at least about 95%, or at least about 99% of the nanostructures and/or microstructures have cross-sectional diameters within these ranges. The cross-sectional diameter of a cylindrical nanostructure and/or microstructure corresponds to the diameter of the cylinder. The cross-sectional diameter of a non-cylindrical nanostructure and/or microstructure (e.g., hole) corresponds to the diameter of a cylinder having the same volume and the same depth (measured parallel to the thickness of the layer in which the region is formed) as the non-cylindrical region. In some cases, the depth of the nanostructures is negligible (e.g., the depth is <5% the thickness of the substrate material) when compared to the thickness of the substrate. For example, in one embodiment, the nanostructure depth is approximately 1-2 micrometers and the substrate has a thickness of about 300-500 micrometers. In embodiments wherein the nanostructures form trenches, grooves, or crevices in the surface, the average cross-sectional diameter may refer to the width of the trenches, grooves, or crevices. The ratio of the width to the length of the trenches, grooves, or crevices may be at least 1:10, at least 1:20, at least 1:25, at least 1:50, at least 1:100, at least 1:200, at least 1:300, at least 1:400, at least 1:500, at least 1:600, at least 1:700, at least 1:800, at least 1:900, at least 1:1000, or greater.

The nanostructures and/or microstructures can be spaced apart from each other periodically or aperiodically. In some embodiments, the average of the nearest neighbor distances between the nanostructures is between about 10 nm and about 100 microns, between about 100 nm and about 10 microns, or between about 0.5 microns and about 2 microns. The nearest neighbor distance for a first nanostructure is calculated as the distance between the center of the first nanostructure and the center of the nearest nanostructure proximate the first nanostructure.

Any suitable number of nanostructures may be formed in at least one surface of the substrate material. In some cases, at least one nanostructure is formed. In some cases, at least or about 10, at least or about 100, at least or about 500, at least or about 1000, at least or about 5000, at least or about 10,000, at least or about 50,000, at least or about 100,000, at least or about 500,000, at least or about 1,000,000, at least or about 5,000,000, at least or about 10,000,000, or more, nanostructures are formed in the at least one (or in some cases, one) surface of the substrate material. Those of ordinary skill in the art will be aware of suitable techniques for forming nanostructures in the surface of a substrate material, including, but not limited to, micromachining, film deposition processes such as spin coating and chemical vapor deposition, laser fabrication, photolithographic techniques, etching methods including wet chemical or plasma processes, electrochemical processes, and the like.

The nanostructures formed on the surface of the substrate material may have any suitable density. In some cases, the density may be about 10,000, about 100,000, about 500,000, about 1,000,000, about 5,000,000, about 10,000,000, or more nanostructures (e.g., holes) per mm² of the surface of the substrate material.

In some embodiments, a filler material is formed in at least a portion of each of the nanostructures. In some embodiments, the filler material fills or substantially fills the nanostructures. As described herein, the presence of the filler material in the nanostructures may prevent or reduce thermal degradation which may occur during and/or following heating of the substrate material. That is, the presence of the filler material may prevent and/or minimize the nanostructures from collapsing or otherwise deforming during heating. As will be understood by those of ordinary skill in the art, selection of the filler material generally depends on the selected substrate material and the selected application, and accordingly, guidelines are now provided for appropriate selection of a filler material.

In some embodiments, the filler material is transparent or substantially transparent. Generally, the filler material is selected to be optically transparent at the desired wavelengths for the application and/or substrate material. For example, if the substrate material is to absorb and/or emit energy of certain wavelengths, the filler material should generally be selected to be optically transparent for those selected wavelengths. Additionally, the thermal expansion coefficient of the filler material as compared to the substrate material should be generally considered. Without wishing to be bound by theory, if the thermal expansion coefficients of the filler material and the substrate material are too different, upon heating, the filler material and/or substrate material may expand and/or compress to a greater extend as compared to the substrate material and/or filler material, respectively, and thus, the nanostructures formed in the surface of the substrate material may be deformed due to unbalanced expansion and/or compression. In some embodiments, the filler material is IR transparent or substantially IR transparent.

In some embodiments, the filler material has a thermal expansion coefficient within about 10, or about 9, or about 8, or about 7, or about 6, or about 5, or about 4, or about 3, or about 2 orders of magnitude, or is approximately equal to, the thermal expansion coefficient of the substrate material. In some cases, the filler material and the substrate material have positive thermal expansion coefficients. In other cases, however, one or more of the filler material and the substrate material have negative thermal expansion coefficients. In some cases, the thermal expansion coefficient mismatch between the filler material and the substrate material is than 50%, less than 40%, less than 30%, less than 20%, less than 10%, less than 5%, less than 4%, less than 3%, less than 2%, or less than 1%, wherein the mismatch is determined by dividing the absolute value of the difference between the thermal expansion coefficients of the substrate material and the filler material (e.g., |difference between the thermal expansion coefficients of the substrate material and the filler material|) divided by the smallest absolute value of either the substrate material or the filler material thermal expansion coefficient (e.g., |substrate material thermal expansion coefficient| or |filler material thermal expansion coefficient), whichever is less), multiplied by 100%.

Table 1 provides non-limiting examples of filler materials. In some cases, the filler material is a ceramic material. In some cases, the filler material is ZnO₂.

TABLE 1

| | | | Thermal | | |
|---|---|---|---|---|---|
| | Melting | Working | Expansion | Young's | |
| | Temp | Temp | Coefficient | Modulus | Optical |
| Material | (° C.) | (° C.) | (×10⁻⁶) | (GPa) | Properties |
| W | 3442 | <1700 | 4.3 | 411 | Radiate |
| Ta | 3017 | <1375 | 6.3 | 186 | Radiate |
| Si | 1414 | <1000 | 3.0 | 150 | Radiate |
| SiO₂ | 1600 | <1300 | 0.4 | 73 | Transparent |
| | | | | | RI = 1.46 |
| Si₃Nₓ | 1900 | <1200 | 3.3 | 310 | Transparent |
| | | | | | RI = 2.05 |
| SiC | — | <1650 | 4.0 | 410 | Semi- |
| | | | | | Transparent |
| | | | | | RI = 1.9-2.4 |
| SiOC | — | <1600 | 3.5 | 100 | Semi- |
| | | | | | Transparent |
| | | | | | RI = 1.5-3.2 |
| HfO₂ | 2758 | <1500 or | 5.9 | 78 or 220 | 0.25-10 um |
| | | <2000 | | | Transparent |
| | | | | | (semi- |
| | | | | | transparent) |
| TiN | 2930 | <2500 or | 9.36 | 590 or 251 | Semi- |
| | | <1500 | | | Transparent |
| Graphite | — | Very high | 1.2-8.2 | 8-15 | Opaque |
| MgO | 2852 | <2000 | 8 | 295 | Transparent |
| ZrO₂ | 2715 | <1500 or | 10.3 | 200 | 0.3-7 um |
| | | <2500 | | | Transparent |

Those of ordinary skill in the art will be aware of suitable methods for filling the nanostructures with the filler material. In some cases, the filler material may be applied to the nanostructures manually (e.g., with tools, a squeegee, etc.). In other cases, a filler material may be applied using techniques including, but not limited to, sputtering, ink-jet printing, and electrolytic deposition. In some cases, the filler material may be applied using solution-based and/or gel or sol-gel coating techniques. For example, in some embodiments, a solution of a material may be spin coated onto the surface of the substrate, the excess solution may be removed (e.g., by wiping, brushing, evaporation), and the material may precipitate in on the substrate (e.g., in at least a portion of the nanostructures).

In some embodiments, a first film is positioned or formed between the substrate material and the filler material (e.g., present in the nanostructures). Generally, the first film is applied to the surface of the at least one nanostructure in the surface of the substrate material, following by filling the at least one nanostructure with the filler material. In some embodiments, the film may act as a diffusion barrier and/or adhesion layer. For example, in some cases, the film may act to prevent or reduce diffusion of the filler material to the surrounding substrate material or vice versa, for example, while it is heated. In some cases, the film may also reduce or prevent surface oxidation from occurring (e.g., due to the presence of oxygen in the atmosphere during heating). In some cases, the film may aid in the adhesion of the substrate material to the filler material.

In some embodiments, a second film is provided to and/or formed on the article following filling of the nanostructures, and optionally polishing and/or smoothing of the surface of the article. The second film may prevent surface oxidation of the outer surfaces of the substrate material.

The first film and/or the second film may be formed of any suitable material and may be of any suitable thickness. In some cases, the first film and/or second film is substantially transparent, or is of a thickness wherein the first film and/or second film does not substantially affect the transmission of energy through the film (e.g., the incident light and/or emitted light).

In some embodiments, a film has an average thickness of less than or about 1000 nm, less than or about 900 nm, less than or about 800 nm, less than or about 700 nm, less than or about 600 nm, less than or about 500 nm, less than or about 400 nm, less than or about 300 nm, less than or about 200 nm, less than or about 100 nm, less than or about 90 nm, less than or about 80 nm, less than or about 70 nm, less than or about 60 nm, less than or about 50 nm, less than or about 40 nm, less than or about 30 nm, less than or about 20 nm, less than or about 10 nm, less than or about 9 nm, less than or about 8 nm, less than or about 7 nm, less than or about 6 nm, less than or about 5 nm, less than or about 4 nm, less than or about 3 nm, less than or about 2 nm, less than or about 1 nm, or between about 1 nm and about 10 nm, or between about 2 nm and about 10 nm, or between about 3 nm and about 8 nm, or between about 5 nm and about 8 nm.

Those of ordinary skill in the art will be able to select appropriate materials for forming a film. Non-limiting examples of materials for the film include, but are not limited to, TiN, TaN, Al₂O₃, HfO₂, and SiC. In some cases, the film material is substantially stable or stable under high temperatures (e.g., greater than about 800° C.)

Those of ordinary skill in the art will be aware of methods for forming films of the material on the surface of the nanostructures and/or the surface of an article. Non-limiting methods include spin-coating, drop-casting, dip coating, roll coating, screen coating, a spray coating, screen printing, ink-jet printing, and the like.

Following filling the nanostructures with a filler material, the surface of the substrate material having the nanostructures may be polished or smoothed, such that the substrate material surface and the surface of the filler material formed in the nanostructures are approximately planar. This may be important for application involving photonic crystals. Polishing and smoothing techniques will be known to those of skill in the art (e.g., chemo-mechanical polishing).

As noted above, following filling of the nanostructures with the filler material, and the optional polishing/smoothing step, a second film may be applied to the surface of the substrate material comprising the nanostructures and/or the exposed surface of the filler material. The second film may comprise the same or different materials than the first film, and generally comprises the same properties as the first film (e.g., stable at high temperatures, etc.).

In some embodiments, one or more annealing steps may also be carried during the formation of the article. In some cases, an annealing step may be conducted on the substrate material prior to formation of the at least one nanostructure on the surface of the substrate material. In some cases, an annealing step may be conducted on the substrate material following to formation of the at least one nanostructure in the surface of the substrate material but prior to forming a film and/or the filler material in the at least one nanostructure. In some cases, an annealing step may be conducted on the article following filling the at least one nanostructure with at least one filler material.

An article as described herein (e.g., comprising a substrate material comprising at least one nanostructure, a filler material formed in the at least one nanostructure, and optionally at least one film form between the filler material and the substrate material) and/or an article formed according to a method described herein may find use in a variety of applications. In some cases, the application may involve exposing the article to a high temperature (e.g., >800° C.) or a range of high temperatures. In some cases, the temperature or range of temperatures is between 800° C. and 1200° C., or between 800° C. and 1100° C. In some embodiments, the at least one nanostructure is structurally stable or substantially structural stable following and/or during heating of the article to high temperature. For example, the cross-section diameter and/or the depth of the at least one nanostructure changes by less than about 1%, about 2%, about 3%, about 4%, about 5%, about 6%, about 7%, about 8%, about 9%, about 10%, about 15%, or about 20%, following heating of the article at a temperature of about 800° C., about 850° C., about 900° C., about 1000° C., about 1100° C., about 1200° C., or higher, for a period of time of about 10 minutes, about 20 minutes, about 30 minutes, about 45 minutes, about 60 minutes, about 2 hours, about 3 hours, about 4 hours, about 6 hours, about 12 hours, about 24 hours, or longer. In a particular embodiment, the cross-section diameter and/or the depth of the at least one nanostructure changes by less than about 1%, about 2%, about 3%, about 4%, about 5%, about 6%, about 7%, about 8%, about 9%, or about 10%, following heating of the article at a temperature of about 850° C. for a period of time of at least about 60 minutes, about 2 hours, about 3 hours, about 4 hours, about 6 hours, about 12 hours, about 24 hours, or longer. In some embodiments, the heating occurs in the absence of oxygen gas and/or water vapor.

As will be understood by those of ordinary skill in the art, the invention will find use not only in a variety of materials, but in connection with a variety of applications for uses. For example, the invention can find use in adding robustness to materials involved in light emission (e.g., materials for lighting such as standard in residential, industrial, and/or outdoor lighting), displays, electromagnetic radiation absorbers such as sensors, or the like, electromagnetic radiation-transparent objects such as shields for light emitters, optical filters, and the like. Those of ordinary skill in the art will understand that different systems will operate at different temperatures and/or through different temperature ranges and the user will select different materials for different applications. With the benefit of the invention as disclosed herein and knowledge of material properties, those of ordinary skill in the art can do so. In addition, the user can be assisted by a simple screening techniques including, but not limited to, those related to melting temperature, crystal structure (single crystalline or poly crystalline: grain growth and recrystallization issue), thermal expansion coefficient, optical transparency at given wavelength, Young's modulus, material cost, and/or availability.

In some cases, an article as described herein and/or formed according to the methods described herein may be employed in a thermophotovoltaic system. In some cases, an article may be employed in lighting systems, for example, for use in tungsten-filament electric light bulbs. In some cases, an article as described herein and/or formed according to the methods described herein may be employed in incandescent lighting applications (e.g., wherein the nanostructures comprises grooves, trenches, or crevices).

U.S. Provisional Patent Application Ser. No. 61/563,396, filed Nov. 23, 2011, and entitled “ARTICLES, SYSTEMS, AND METHODS RELATING TO THERMAL STABILITY OF NANOSTRUCTURED AND/OR MICROSTRUCTURED MATERIALS” to Lee et al., is incorporated herein by reference in its entirety for all purposes

The following examples are intended to illustrate certain embodiments of the present invention, but do not exemplify the full scope of the invention.

### EXAMPLE 1

This example generally relates to thermal stability of nanostructured substrate materials.

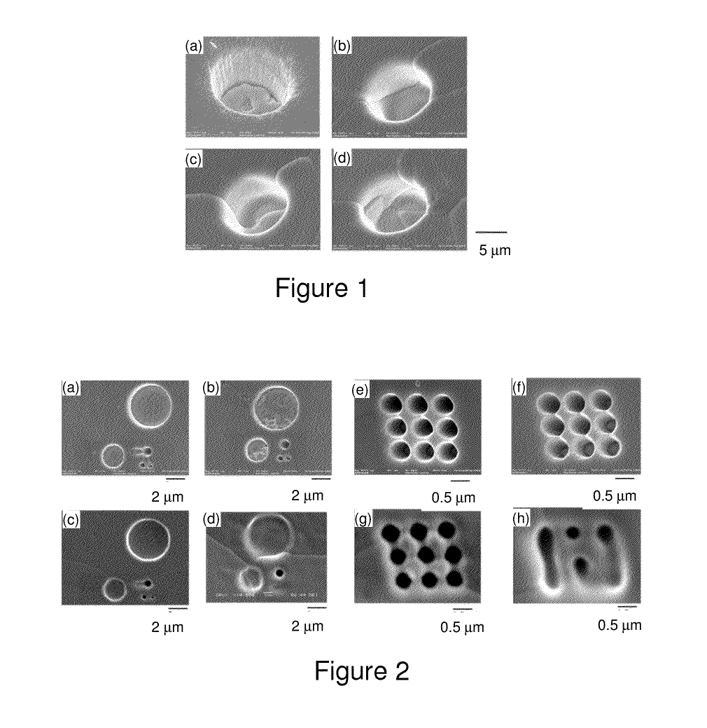

There are three main modes by which nanostructures can be deformed when heated: recrystallization and grain growth, oxidation, and surface diffusion. To identify the problems of thermal degradation, the tungsten samples were prepared and a firing test was performed. A 10 mm by 10 mm polycrystalline tungsten sample was prepared by mechanical polishing. The surface roughness was less than 0.5 μm, and the sample thickness was 300 μm. The sample was fired in an oxygen free condition for 100 hours at 1200° C. with the temperature gradually increasing to 1200° C. at the rate of 3° C./min. To remove possible oxygen molecules on the surface, a forming gas, hydrogen (5%) and nitrogen (95%) are flown in at a rate of 150 sccm. The hot sample was then cooled down to room temperature at the rate of 3° C./min. The samples were studied using SEM. As seen in FIG. 1, recrystallization along with surface diffusion occurred. Thermal oxidation took place during the firing test at 30 hours at 1200° C. There was a slight crack found on the furnace tube which may have caused the oxidation.

In FIG. 1: Thermal stability test of micro holes on tungsten surface (a) polished surface with focused ion-milled 5 μm diameter and 2 μm deep trenches, (b), (c) and (d) 100 hours annealing at 1,200° C. (Grain growth and surface diffusion were observed). The annealing of tungsten samples was then investigated in various low oxygen partial pressures using X-ray diffraction to track the presence of tungsten trioxide (WO₃). At a controlled condition with forming gas supply, oxidation occurred, as verified by XRD data analysis.

Recrystallization and grain growth generally occurs when a material has stored energy due to deformation, such as after cold rolling. If these stresses are relaxed by a pre-annealing process, the small grains may be recrystallized to certain level of stable size and the effect of grain growth may be minimized With a 100 hours pre-annealed sample at 1200° C., the speed of grain growth was observed to level off and the average grain size was approximately 50 mm diameter. Since the dimension of the pattern is in the order of hundreds nanometer, the pattern inside the grain boundary may survive, but the pattern on the grain boundary may not. With 100 hours pre-annealed sample at 1200° C., the grain structure was observed after an additional 40 hours annealing at 1200° C. (see FIG. 2).

In FIG. 2: (a) 100 hours pre-annealed at 1200° C. before drilling the holes, (b) non-treated polished tungsten with drilled holes, (c) and (d) 100 hours firing at 1200° C. in oxidation free condition. (e) and (f) are treated under same method with (a) and (d) but with nano scale holes, diameter of 300 nm, (g) and (f) are images after 100 hours firing at 1200° C.

The TiN film (with O₂ stuffing) coated sample did not show significant oxidation after 30 hours of test at 1200° C., which was expected to provide a sufficient barrier layer on top of the tungsten emitter. The TiN coated sample was achieved by sputtering at 400° C. and then baked at 300° C. for 30 min in air for stuffing oxygen. The oxygen stuffing on sputtered TiN may enhance the diffusion barrier quality since sputtered TiN has columnar structure and oxygen may fill the gap between the grains by stuffing method.

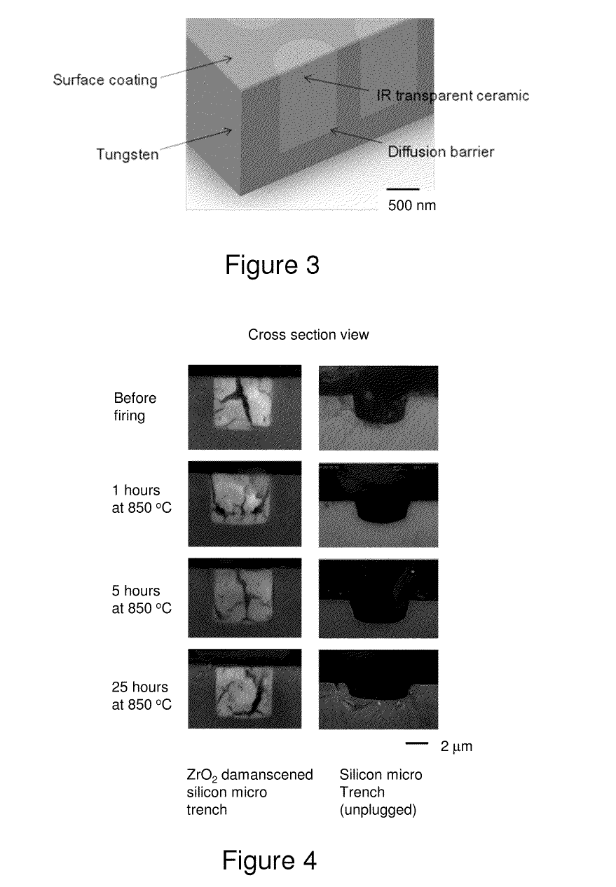

The design idea that was implemented is the flat surface tungsten photonic crystal (FSTPC). By replacing the air in the nano-holes with a damascened IR transparent ceramic material, the surface of the emitter may have negligible second derivative of the curvature, which can then minimize or eliminate the surface diffusion even at high temperatures. A thin layer of diffusion barrier can prevent oxidation and maintain the nanostructure along with its optical performance (see FIG. 3).

In FIG. 3: Flat Surface Tungsten Photonic Crystal (FSTPC): tungsten subtract drilled cylindrical nano trenches, thin layer of diffusion barrier coated, IR transparent ceramic plugged, (after flattening the surface by CMP) the surface coated thin layer of oxidation and surface diffusion barrier (cross-sectional view).

Silicone micro trenches and holes were fabricated. Silicon has smaller thermal expansion coefficient than tungsten (Si: 3.0×10⁻⁶ m/K and W: 4.5×10⁻⁶ m/K), and the filler material selected has comparable thermal expansion coefficient (ZrO₂, thermal expansion coefficient: 10.3×10⁻⁶ m/K). A sample was filled with ZrO₂ followed by a thin layer of diffusion barrier coating; the surface was then flushed with Chemo-mechanical polishing (CMP) and then coated with a thin layer of diffusion and oxidation barrier. ZrO₂ coating was achieved by brushing ZrO₂ sol-gel using cotton swabs multiple times. For each brushing, pyrolysis and annealing were done at 350° C. and 650° C. by using rapid thermal process (RTP). Another sample prepared was a bare silicon microtrenches without any coating or plugging.

Samples with the same size of microtrench and damascened trench were fired for 25 hours at 850° C. and the cross-sectional views of each sample were observed with a scanning electrode microscope at 1 hour, 5 hours, and 25 hours. The damascening ZrO₂ prevented significant thermal degradation of the microstructures.

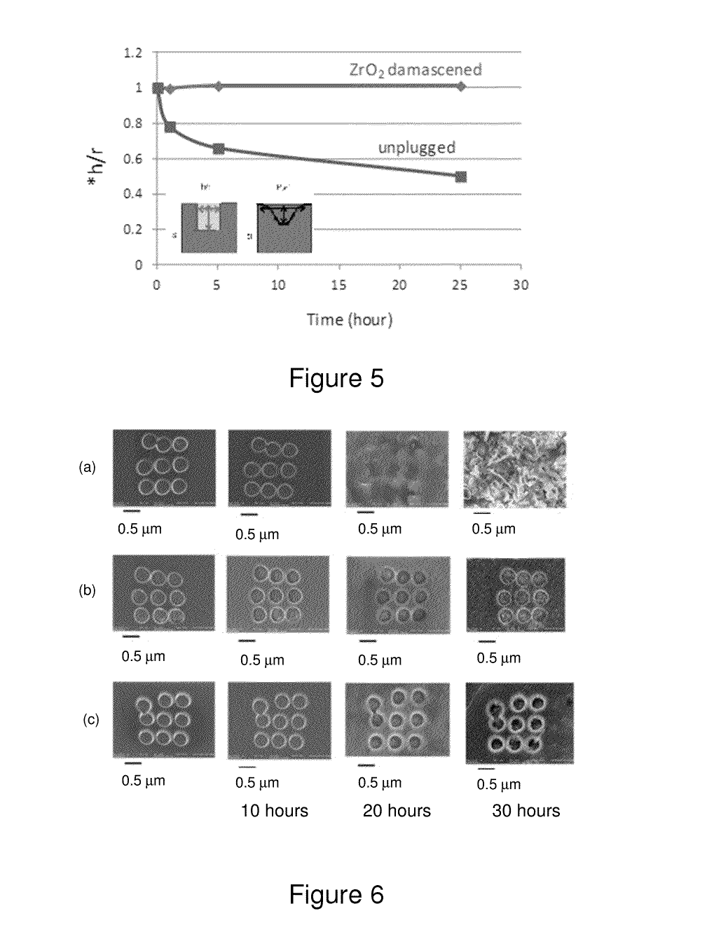

FIG. 4 shows the cross-sectional images of the silicon microtrenched with ZrO₂ filled holes and coatings with respect to the firing times (left column) and silicon microtrenches (right column) without fillers or coatings. The plugging IR transparent ceramic prevented significant structural degradation of the microstructure. The qualitative degradation data are shown in FIG. 5. The depth to radius ratio was measured at each point and compared to each other in a normalized unit.

In FIG. 4: Firing test results at 850° C. Images were taken with SEM after 1 hour, 5 hours, and 25 hours firing.

In FIG. 5: Depth to radius ratio with respect to firing time. The y-axis is normalized number for direct comparison.

The ZrO₂ plugged structure were barely deformed or degraded while the bare silicon trenches lost their structural integrity.

The thermal stability of micro/nanostructures for selective emitter was significantly improved by damascening IR transparent material and by providing a surface diffusion barrier on top of it.

### EXAMPLE 2

This example relates to the thermal stability of selective emitters for solar thermophotovoltaic (STPV) systems for enhancing conversion efficiency. 2-D photonic crystals are periodic micro/nano-scale structures that are designed to affect the motion of photons at certain wavelengths. The structured patterns, however, can lose their structural integrity at high temperature, which disrupts the tight tolerances required for spectral control of the thermal emitters. Through analytical studies and experimental observations, four major mechanisms of thermal degradation of 2-D photonic crystal have been identified: oxidation, grain growth and re-crystallization, surface diffusion, and evaporation and re-condensation. In this example, the design of a flat surface photonic crystal (FSPC) are described and prepared. The FSPC design includes a thin diffusion barrier layer to prevent oxidation and evaporation while maintaining optical performance. Pre-annealing or the use of single crystalline tungsten was employed to prevent grain growth. By replacing the air in micro/nano-scale holes with a damascened IR transparent ceramic material, the surface of the emitter had negligible second derivative of the curvature, which minimized the surface diffusion even at high temperatures. Acceleration tests on silicon-based FSPC showed that the micro/nano-scale structures survived for at least 100 hours at 400° C.

Introduction: The solar thermophotovoltaic (STPV) system is a novel approach to overcome Shockley-Queisser limit of photovoltaic (PV) systems through the control of absorption and emission spectra. Since STPV is not subject to the same limitations as conventional PV systems, STPV has the potential to greatly improve energy conversion efficiency in commercial products. In STPV, a broad range of solar radiation can be absorbed with a selective absorber and the absorbed energy is converted to heat and transferred to the selective emitters. Selective emitters can selectively emit the wavelength shorter than the band-gap wavelength of PV diodes through a process called Q-matching. Q-matching can be achieved with periodic photonic crystal structures and selectivity can be improved with increasing micro/nano-scale structure dimension. 2-D photonic crystals are most common choice for emitters based on their manufacturability, low cost, and Q-matching performance. By controlling the emission spectrum, the theoretical conversion efficiency of at least 85.4% may be achieved with emitter temperature at 2271° C. .

The system's conversion efficiency is usually determined by the cut-off wavelength of the selective emitter, band-gap of PV diode, and operating temperature of the selective emitters. After Q-matching, the conversion efficiency is a function of emitter's temperature, and the efficiency proportionally increases with the 4^{th} power of emitter's operating temperature. For increased efficiency, the emitter should operate at elevated temperatures. However, the micro/nano-scale structures used for controlling emission spectrum generally degrade quickly at temperatures larger than 800° C. In this regards, most of the TPV systems operate at below 800° C. reducing the conversion efficiency to below 20%. Therefore, their efficiency-cost properties are often rather poor compared to other electricity-generating technologies. A thermally stable selective emitters capable of surviving at least for 10 years at temperatures of 800-1100° C. could be designed to overcome this fundamental problem and improve conversion efficiency.

Thermal Failure Modes: Nano or micro-scale structures on selective emitters generally degrade or in extreme cases, disappear when exposed to high temperatures over time. Since the TPV is expected to operate over 10s of years, the survival of the nano/micro-scale patterned emitters at high temperature over long periods of time is a significant challenge in successful emitter design. Initially, identification of failure modes was prioritized to seek solutions for preventing thermal degradation of micro/nano-scale structures. Firing tests were performed and the results observed with polycrystalline and single-crystal tungsten samples at 1200° C. (Tₕ=0.4) and confirmed with silicon samples at 400° C. (Tₕ=0.4). The major degradation modes found were oxidation, grain growth, surface diffusion, and evaporation and re-condensation.

Although modes could potentially be coupled, independent solutions to prevent or minimize the thermal degradation were suggested through observation and physical models for each thermal degradation mode.

Thermal Oxidation: Oxidation may impact the geometry of micro/nano-scale structures on the surfaces, and in the case of selective emitters, any chemical change can significantly alter the emitted spectrum. For example, in air, tungsten begins to oxidize at room temperature with significant oxidation occurring around 400-500° C. Tungsten trioxide (WO₃) is permeable to oxygen which allows the oxide layer to grow quickly. If tungsten is heated further, sublimation begins around 750° C. It is therefore important to understand the relationship between the oxidation rate, the partial pressure of oxygen, and the temperature.

This highlights the challenge presented for preventing oxidation and the importance of a good diffusion barrier coating. For high temperature diffusion barriers, titanium nitride (TiN) and oxygen stuffed TiN, which has shown to enhance the diffusion barrier, can minimize oxidation. Single-crystal tungsten was polished and nano-scale holes were drilled with focused ion beam (FIB) milling. Samples with identical geometry were prepared for firing tests with different surface coatings conditions: untreated, TiN coated, and oxygen stuffed TiN coating. After firing for 30 hours at 1200° C. with nitrogen flow at 5 sccm, nearly complete oxidation of the untreated tungsten surface is observed, and the oxygen stuffed TiN coating showed minimal deformation via oxidation (FIG. 6). Through the firing test, a 5-7 nm-thick coating of TiN with oxygen stuffing was found to be effective for minimizing oxidation.

FIG. 6 shows oxidation of tungsten surface. (a) un-treated sample, (b) TiN coated, and (c) TiN coated and oxygen stuffed. Images captured every 10 hours after firing at 1200° C. Total 30-hour firing test results under nitrogen flowing at 5 sccm. Ramped up and down at a rate of 3° C./min.

### Experiments:

Grain Growth and Recrystallization: When a strain-hardened material is held at an elevated temperature, an increase in atomic diffusion occurs that can relieve some of the internal strain energy. When the bond energy is exceeded, excited atoms in severely strained regions can break their bonds and move to locations of lower strain. This process, known as recovery, can result in reduced the internal residual stress through a movement of dislocations to lower-energy positions. With further temperature increase, recrystallization occurs when new, strain-free grains nucleate and grow inside the old distorted grains and at the grain boundaries, replacing the deformed grains produced by the strain hardening. The extent of recrystallization depends on many factors including temperature, time at that temperature, and the amount of previous strain hardening. If a specimen is maintained at the high temperature beyond the time needed for complete recrystallization, the grains can begin to grow in size. Grain growth can occur when recovery and recrystallization are complete and further reduction in the internal energy can be achieved by reducing the total area of the grain boundaries.

For 2-D photonic crystals, the micro/nano-scale structure is smaller than or on similar order as the grain size. As a result, if the fabricated arrays of 2-D photonic crystal experience recrystallization or grain growth, the physical geometry of the micro/nano features could be altered resulting in inferior optical performance as selective emitters. Most commonly, poly-crystalline tungsten sheets are work hardened when produced via a rolling process. Pure tungsten has a very high recrystallization temperature of approximately 1350° C.; however, recovery starts at around 300° C. Therefore, grain growth can start without recrystallization, and, the photonic crystal structure of a poly-crystalline substrate can deform or migrate at the general operation temperature of TPV (800-1300° C.).

Firing experiments were conducted to observe grain growth of a polycrystalline tungsten sample. 300 μm thick, 10 mm×10 mm polycrystalline tungsten samples with surface roughness <0.5 μm were prepared via mechanical polishing. Holes 5 μm-diameter and 2 μm deep were drilled using focused-ion-beam milling process (beam size 11, dose 20 with Joel 4600). The sample was then fired in an oxygen free condition at 1200° C. for 100 hours. Ramp up/down temperature was gradually increased/decreased at a rate of 3° C./min to 1200° C. During firing and subsequent ramp down at a rate of 3° C./min, forming gas, hydrogen (5%) and nitrogen (95%), was allowed to flow at 150 sccm to remove possible oxygen molecules on the surface. After 100 hours of firing, scanning electron microscope (SEM) images of the micro-holes reveals the recrystallization, grain growth, and surface diffusion (FIG. 1).

Grain growth may be prevented by using single crystal material. However, pre-annealing the samples prior to micro/nano fabrication on the surface can also minimize the effect of grain growth. Since primary-recrystallization and grain growth can occur when the material has stored energy due to deformation, pre-annealing can relax these stresses and recrystallize small grains to a stable size effectively minimizing grain growth.

Surface Diffusion: Thermally driven diffusion of atoms generally constantly occurs in materials. While it tends to be negligible in solids at low temperatures, as the temperature increases, the rate at which diffusion occurs can begin to dominate the evolution of the material geometry. In the case of micro/nano-scale structures, surface diffusion tends to dominate over bulk diffusion.

To investigate surface diffusion further, a theoretical modeling of the micro/nano-scale structure thermal degradation was proposed. Based on Mullin's analysis, Equation 1, the second derivative of the curvature along the surface

$$\frac{{\partial }^{2} K}{\partial {s}^{2}} ,$$

pressure, and temperature are the key parameters that affect the spatial distribution of surface diffusion. Since the operational conditions can be modeled as isothermal and isobaric, surface diffusion can be determined by the second derivative of curvature. The velocity of the surface in the normal direction, v, is then given by:

$${v}_{n} = {γΩ}^{2} n \frac{{D}_{s}}{kT} \frac{{\partial }^{2} K}{\partial {s}^{2}} \qquad ( 1 )$$

where γ is the interfacial free energy, Ω is the atomic volume, and n is the number of atoms per unit area. Dₛ is the coefficient of surface diffusion, k is Boltzmann constant, T is absolute temperature.

Evaporation and re-condensation: At high temperatures, the amount of material that is vaporized from a solid surface can be significant. This vapor creates a locally high vapor pressure and re-deposits on the surface nearby. The normal surface velocity vₙ by which evaporation and re-condensation is derived:

$${v}_{n} = - \frac{A {Ω}^{2} γ {P}_{eq}}{kT} K$$

where, A is a vapor transport rate constant and P_{eq} is the vapor pressure in equilibrium on a local region of the surface with zero curvature.

Design: The flat surface Photonic Crystal (FSPC) design was proposed based on, in part, the scientific analysis of fundamental sources of thermal degradation in micro/nano-scale structures. Surface diffusion and evaporation and re-condensation are unavoidable phenomena in micro/nano-scale structures at high temperatures and highly depend on the material properties and surface geometry. In the temperature range of interest, changes in material properties are small, so thermal degradation was generally dominated by curvature of the surface geometry. Based on Equations (1) and (2), if the curvature is zero, there would be negligible surface evolution through surface diffusion or evaporation and re-condensation.

The proposed FSPC structure was a conventional 2-D photonic crystal coated with a thin inter-diffusion barrier with the micro- and nano-structure plugged with an IR-transparent ceramic. After coating, the top surface was planarized creating a zero-curvature surface to eliminate the effects of surface diffusion and evaporation and re-condensation at high temperature operation (FIG. 3).

An important part of the design is IR optical transparency of the plugging materials and the thin layer of inter-diffusion barrier and oxidation/evaporation barrier. Based on previous results, oxygen stuffed TiN layer was selected as the inter-diffusion barrier material and it was assumed that for small thicknesses (on the order of 5-7 nm), the diffusion barrier would have a negligible influence on the surface optical properties

Another consideration for IR transparency is plugging material selection. In some embodiments, the plugging material ,au be transparent at the wavelength below infra-red, be stable at elevated temperatures over 800° C., and manufacturable with current processing techniques. Materials for high operation temperature and IR transparency are listed in Table 1. Tungsten was the choice for selective emitter due to its high operation temperature and selective emissivity property. When ramping to the high operation temperature, compressive stress may occur while the plugging material and tungsten expand help in mechanically securing the plug inside micro-structure. For this compressive stress to be maintained, the thermal expansion coefficient (TEC) of plugging ceramic can be slightly higher than that of the substrate. For a tungsten photonic crystal, zirconium oxide (ZrO₂) or hafnium oxide (HfO₂) are two possible materials which may be selected based on, in part, its IR transparency, TEC, and thin film manufacturability via a sol-gel deposition process.

If the hole is positively tapered, the plug may pop out due to the interfacial stresses generated by the force on the plug with acting toward outside. Therefore, in some cases, the holes on tungsten can have slight negative-tapering of the side walls. The sub-micron scale scallops produced via deep reactive ion etching process (DRIE), can naturally secure the plugs. If the thermal expansion coefficient of the plugging material is too high, too much compression stress may occur. Stresses distribution around the boundary of tungsten and zirconia at 1200° C. (top view) is obtained from ANSYS programming (FIG. 8(a)). The SEM image of scalloped side-wall by D-RIE on silicon trench is shown by FIG. 8(b).

FIG. 8(a) shows the analysis of the stress distribution when FSTPC was heated up to 1200° C. Plugging material was Zirconia (ZrO₂) and the substrate was tungsten (W). At 1200° C., 1540 MPa compressive stress at the boundary (medium grey), 1400 MPa compressive stress on Zirconia (dark grey), and 0-400 MPa compressive stress on Tungsten (light grey). 8(b) Scalloped side wall of the silicon trench. The image shows the plugged ZrO₂ but cracked.

Fabrication: The initial FSPC design was based on, in part, a single crystal tungsten that drilled using FIB milling to create cylindrical micro/nano-scale holes. A thin diffusion barrier layer of TiN was then coated via reactive sputtering. After IR transparent ceramic was plugged, the surface was planarized by chemical mechanical polishing (CMP). Finally, the surface was coated by a thin layer of oxidation/evaporation barrier.

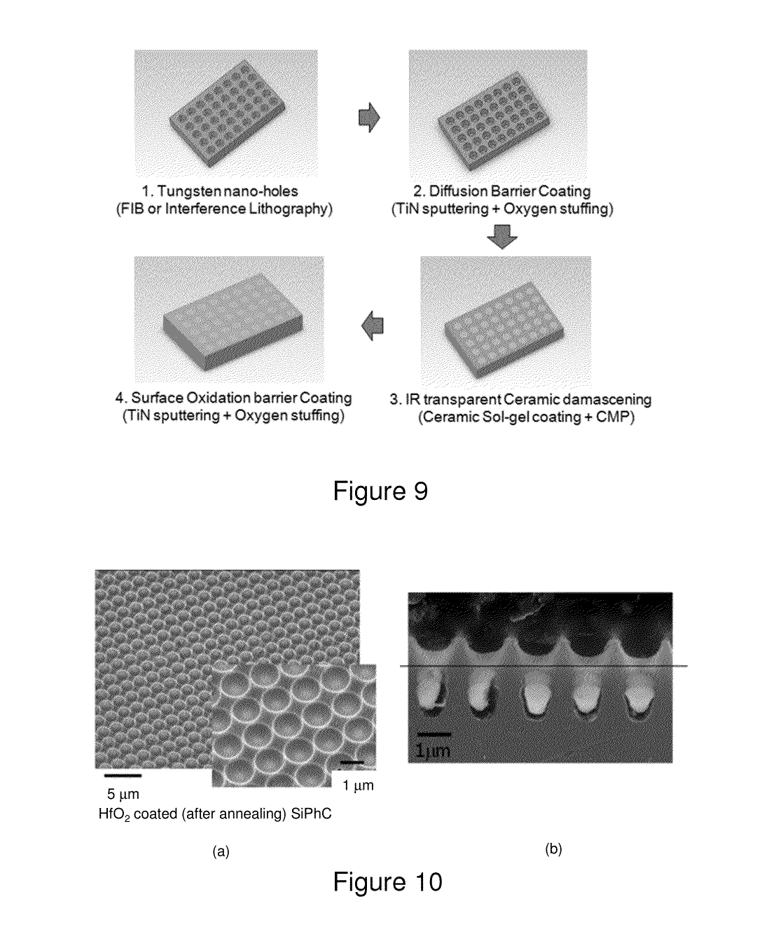

A challenging part of the proposed processes was plugging the ceramic into the nano-pits. Spin coating is one process for zirconium oxide coating on a flat surface. In some cases, the high step on the cylindrical holes may generate uneven stress at the corner which may results in cracks during annealing. Sputtering can also be employed, however dense, but poor step coverage may result in incomplete filling of the holes. Non-uniform thickness might also induce in cracking while annealing the ceramics and is one of the typical failure modes of spin coatings on stepped structures. FIG. 9 shows a process flow of FSPC for tungsten selective emitters.

To fill the micro-scale gap with ZrO₂ solution, a sol-gel method was modified through addition of a brushing step. After spin coating the zirconia solution on the surface of the sample, excess solution was brushed from the surface. In this way, ZrO₂ precipitates could deposit inside the holes and maintain the surface relatively clear until the plugging material to be filled the entire holes. A water-based solution coating method of ceramics was also employed. It is known that hydrolysis and condensation of metal species, while inhibiting the formation of large colloids, converted wet precursor coatings smoothly to dense films. The precursor chemistry allowed a unique densification of the film and enabled the fabrication of crack-free devices. Both ZrO₂ and

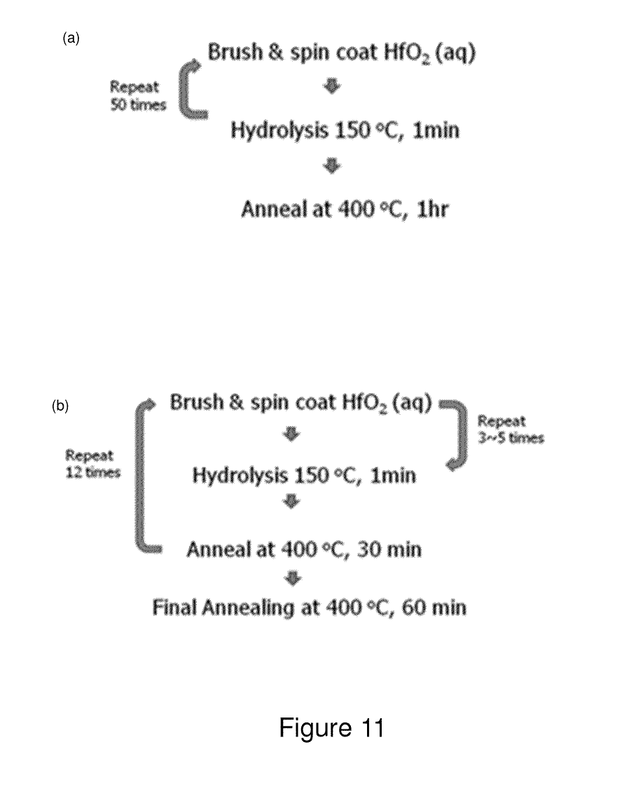

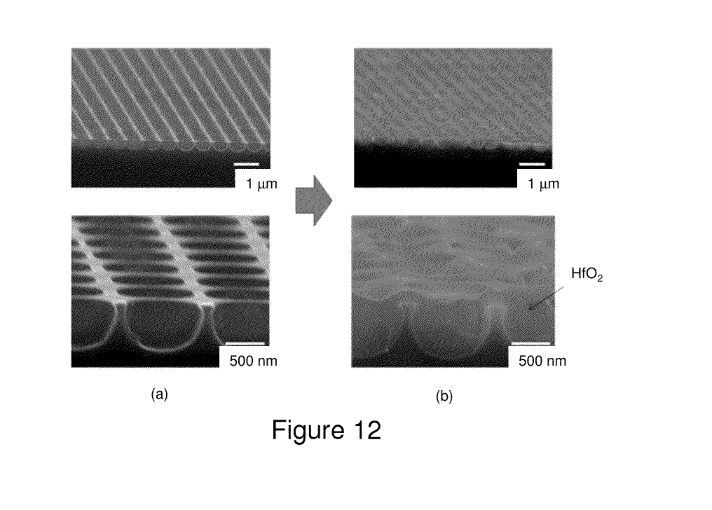

HfO₂ were coated by this water-based method. From Table 1, it is shown that HfO₂ has a higher melting point and its thermal expansion coefficient is much less than that of ZrO₂. HfO₂, itself is also known as a common diffusion barrier material. Finally, the holes were successfully plugged with crack-free HfO₂, and the yield rate was above 90% (FIG. 10(a)). After final annealing, shrinkage of the HfO₂ in the thickness direction was substantial, detaching the plug from the bottom and side walls FIG. 10(b). After the original process (FIG. 11(a)) was modified with intermediate annealing steps (FIG. 11(b)), significant shrinkage was avoided, FIG. 12.

FIG. 10(a) shows crack-free HfO₂ coating on Silicon 2-D photonic crystal after annealing and 10(b) cross-sectional view of HfO₂ filled 2-D Si-PhC. The blue line is its original level surface. The shrinkage along the longitudinal direction is significant but there is no cracking on the plug.

FIG. 11(a) shows a non-limiting synthesis methodology relating to HfO₂ plugging with single final annealing step resulting in significant shrinkage in this embodiment, and FIG. 11(b) shows a modified recipe which minimized shrinkage after annealing, in this embodiment. Intermediate annealing steps were added.

FIG. 12(a) shows 2-D silicon photonic crystal, unplugged, 12(b) crack-free & dense HfO₂ filling (before polishing).

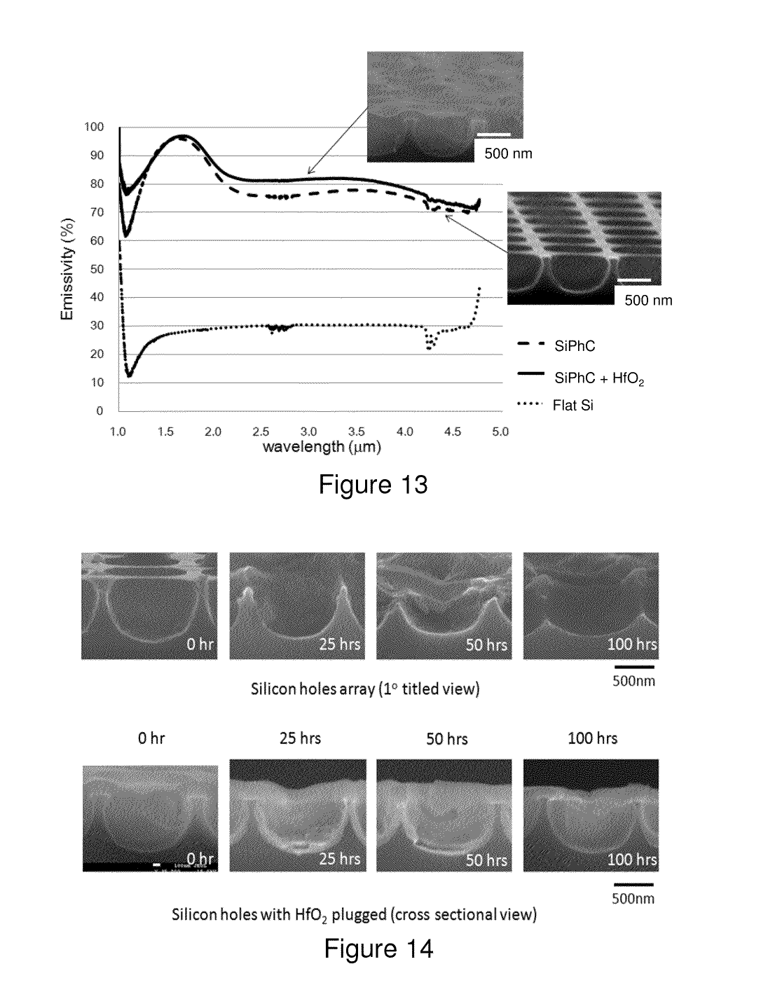

Results: Before and after firing, Fourier transform infrared spectroscopy (FTIR) was used to measure emissivity and determine the optical effect of hafnium oxide plugging material on emitter performance. Since there was little difference in the initial emission spectra of the plugged and unplugged samples (FIG. 13), the HfO₂ was shown to have little effect on the optical properties of silicon 2-D photonic crystal. The unplugged and plugged samples were then fired at 400° C. (Th=0.4) for 100 hours under 5 sccm of nitrogen flow (FIG. 12). SEM cross-sectional images and emissivity measured at 50 hours, 100 hours later were taken to determine thermal degradation. FIGS. 14 show significant thermal degradation of silicon photonic crystal structure and minimal change in the flat surface HfO₂ plugged samples over 100 hours of firing. From FIG. 14, the effects of surface diffusion and evaporation and re-condensation on the untreated samples are clearly shown.

FIG. 13 shows the effect of plugging HfO₂ on silicon photonic crystal. The emissivity difference is less than 5% at wavelengths between 1 to 5 μm.

FIG. 14 shows cross-sectional view of thermal degradation of silicon photonic crystal structures and corresponding SEM images of HfO₂ plugged sample. Fired at 400° C. with nitrogen 5 sccm, and ramp up and down rate of 3° C./min.

Finally, the influence of thermal degradation on optical performance was determined from the emissivity spectra for each sample after 0, 50, and 100 hours fired at 400° C. The silicon photonic crystal emissivity was considerably reduced as the surface thermally degraded, and the final emission curve approaches that of a flat silicon surface. In contrast, the HfO₂ plugged silicon photonic crystal retained its structure when heating and did not lose its optical performance even after 100 hours of firing at 400° C. At the same homologous temperature, Th=0.4, determined by the accelerated lifetime test model, the 2-D tungsten photonic crystal may survive at least 100 hours at an equivalent temperature of 1200° C.

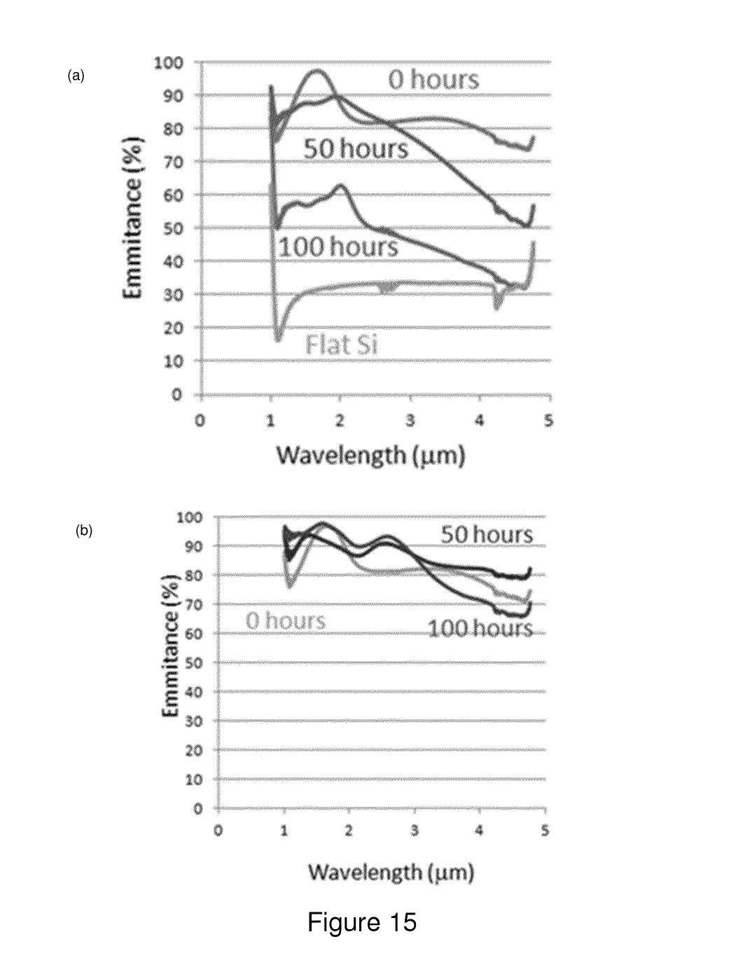

FIG. 15 shows measured emissivity after 0, 50, 100 hours of firing test at 400° C. for: (a) silicon photonic crystal without any treatment (coating or plugging) and (b) HfO2 plugged silicon photonic crystal sample.

Conclusion: Through firing tests with silicon-based flat surface photonic crystal (FSPC), it was observed that plugging transparent ceramic can maintain its original structure for at least 100 hours at homologous temperature (Tₕ) of 0.4. With this FSPC design, tungsten photonic crystal may survived more than 30 years at 1200° C. (Tₕ=0.4), which can significantly improve the current system conversion efficiency.

### EXAMPLE 3

This example describes results relating to the thermal stability and failure modes of selective emitters.

Firing experiments were conducted to observe grain growth of a polycrystalline tungsten sample. 10 mm×10 mm polycrystalline tungsten samples were prepared by mechanical polishing. Surface roughness was less than 0.5 μm and its thickness was 300 μm. First, 20 holes (array of 4 by 5) of 5 μm-diameter were drilled using focused ion-beam milling process. Spacing between the holes was 20 μm and the depth was 5 μm. The sample was fired in an oxygen free condition at 1200° C. for 100 hours.

The samples were observed by SEM at 50 and 100 hours of firing. The temperature was gradually increased to 1200° C. at a rate of 3° C./min and stayed for 50 hours. To remove possible oxygen molecules on the surface, forming gas, hydrogen (5%) and nitrogen (95%), was allowed to flow at 150 sccm. The hot sample was cooled down to room temperature at a rate of 3° C./min under same forming gas flow. A set of SEM images after 50 hours of firing were obtained. The same procedure was repeated for additional 50 hours to obtain 100 hours of firing results. A closer look at the micro holes revealed recrystallization (and/or grain growth) along with the surface diffusion.

Pre-annealing: Using single crystal material can free the samples from the grain growth issue. However, pre-annealing the samples prior to micro/nano fabrication on the surface can also minimize the effect of grain growth. Since primary-recrystallization and grain growth occur when the material has stored energy due to deformation, preannealing could relax these stresses and may recrystallize small grains to a certain level of stable size and minimize the effect of grain growth.

The grain structure was observed after 100 hours pre-annealing at 1200° C. and additional 40 hours annealing at 1,200° C. as shown in FIG. 1. The grain boundaries did not move significantly, i.e., the grain size did not change much during the additional 40 hours.

To see the effect of pre-annealing, two polycrystalline tungsten samples were tested. One was polished, pre-annealed and then drilled with holes using focused ion beam milling (FIB). The other was just drilled with holes using FIB without any other treatment except polishing the surface. Pre-annealing condition was 1,200° C. for 100 hours with ramping up and ramping down at 3° C./min The samples were put together into the furnace with hydrogen (5%) and nitrogen (95%) flowing condition to prevent oxidation. After firing at 1200° C. for 100 hours, the pre-annealing effectively prevented the degradation by grain growth. As it can be seen in FIG. 2, (a) and (e) are pre-annealed samples and (b) and (f) is non-treated samples. These four samples fired at 100 hours at 1200° C. and (c), (d), (g), and (h) are the corresponding SEM images. It was clear that pre-annealed samples survived longer than non-treated samples from the grain growth and/or surface diffusion.

Thermal Oxidation: Tungsten samples were fired in various low-oxygen partial pressures and X-ray diffraction was used to track the presence of tungsten trioxide (WO₃). It was found that even at a controlled condition with forming gas supply, the surface chemistry was changed (oxidized).

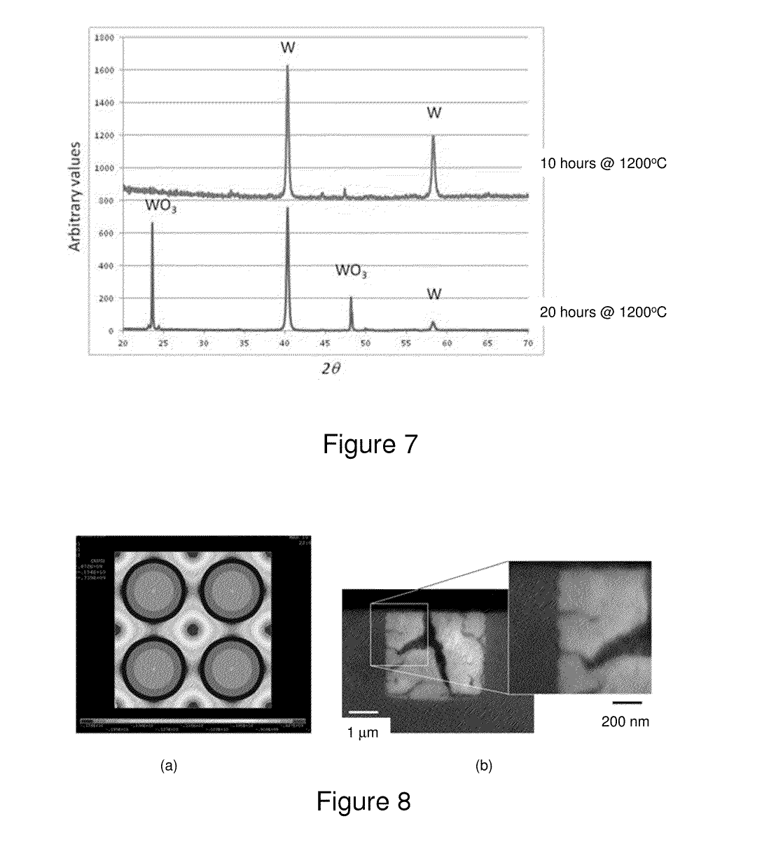

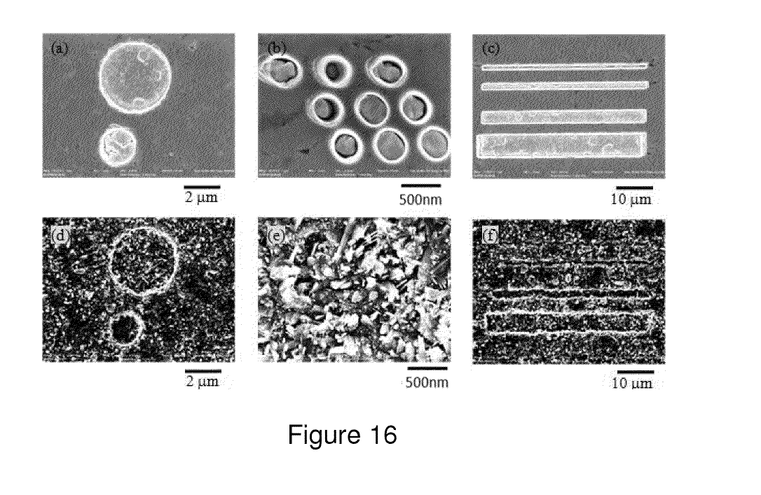

Oxidation: It is estimated that even at a very low partial pressure of oxygen of 10-12 Torr and a temperature of 1,100° C., the surface may oxidize at a rate of approximately 8 nm/day:

$$- \frac{d M}{d t} = 256 \cdot {P}_{{O}_{2}} \cdot {e}^{- ( \frac{25 , 400}{RT} )}$$

where dM/dt is the mass lost to oxidation per unit time in g/cm²/min, T is the absolute temperature in Kelvin, and P_{O2} is the oxygen partial pressure in Torr. This highlights the challenge presented for preventing oxidation, as well as the importance of a good diffusion barrier coating. A single crystalline tungsten sample is prepared, which is free from grain growth and/or recrystallization, was polished and drilled with various shapes and sizes of holes and trenches. To deliver harsh condition on oxidation, rather than hydrogen and nitrogen flow, nitrogen flow was used during the oxidation test. After firing for 30 hours at 1200° C. in nitrogen at 5 sccm flowing condition, the oxidation on the tungsten surface was be observed. In FIG. 16, (a), (b), and (c) are the various size and shapes of trenches, after firing these at 1200° C. for 20 hours, significant degradation of the surface by oxidation was found. The oxidation was verified with XRD analysis. In FIG. 7, the tungsten trioxide peaks appeared after 20 hours firing at 1200° C., which was not detected previously at 10-hour firing.

FIG. 16 shows the oxidation on the tungsten surface after 20 hours of firing at 1200° C. Nitrogen flow was at 5 sccm. (a) is top view of SEM image of 5 μm and 2 μm holes, (b) is 300 nm holes and (c) is the 50 μm-long 500 nm, 1 μm, 2 μm and 5 μm width trenches; (d), (e) and (f) are 20 hours later for each sample from (a), (b) and (c) respectively.

FIG. 7 shows XRD data taken after firing at 1200° C. for 10 and 20 hours. Peaks of tungsten trioxide (WO₃) were weak after 10 hours of firing at 1200° C., which could be observed after 20 hours of firing at same temperature.

Diffusion barrier coating: For high temperature diffusion barrier, titanium nitride (TiN), tantalum nitride (TaN), Aluminum oxide (Al₂O₃), hafnium oxide (HfO₂), and silicon carbide (SiC) are common materials to be coated on the metal surface. However, the oxides have relatively weak adhesion on metal surface and SiC has relatively low melting temperature compared to TiN or TaN. TiN was chosen since it has a smaller thermal expansion coefficient compared to W. It is also reported that oxygen stuffing on sputtered TiN can enhance the diffusion barrier quality since sputtered TiN has columnar structure and oxygen can fill the gap between the grains by stuffing method.

Test with TiN coating: TiN layer, coated by sputtering, can be a solution for preventing oxidation. To have dense diffusion bather, the samples were TiN coated by sputtering at 400° C. and then heated at 300° C. for 30 min in air for stuffing oxygen. Through the firing tests, it was found that 5-7 nm-thick coating of TiN was effective. Three different samples were prepared: (a) TiN coated, (b) TiN coated with oxygen stuffing, and (c) exposed tungsten samples without any coating. These samples were fired at 1200° C. for 30 hours, and after every 10 hours, SEM images were obtained for each sample. The TiN coated samples survived but the samples without the TiN barrier, were destroyed.

Experiments for surface diffusion: Single crystalline tungsten and silicon samples were prepared for firing tests. To avoid coupled effects of grain growth or recrystallization, single crystalline materials were chosen. To minimize oxidation, in addition to nitrogen, hydrogen (5%, 20 sccm) was flown during the entire time of the firing tests. For observation of surface diffusion on single crystalline tungsten and silicon, prepared samples were not coated with a diffusion barrier.

Tungsten micro/nano-holes were fabricated using focused ion beam milling Silicon micro-trenches and nano-holes were fabricated using interference lithography and dry etching techniques.

Firing tests with tungsten sample were challenging due to: fabrication, cross sectional observation, and firing test setup. In this reason, silicon samples were prepared. Compared to tungsten, silicon fabrication processes are well developed and material price is also lower. It has been reported that materials behaviors at high temperature, such as surface diffusion, are showing universalities in solid materials with its homologous temperature, Tₕ. The homologous temperature is the ratio of absolute temperature to its melting temperature.

In this regards, firing tests were conducted on silicon samples. The silicon micro-trench was fired for 25 hours at 850° C. (Tₕ=0.67), and submicron holes array on silicon was fired for 100 hours at 400° C. (Tₕ=0.4). In both cases, the width (radius) increased and the depth got shallow with time. Based on, in part, the modeling and simulation, the parameter, h/r, which is the ratio of the depth of the hole to the radius (or half of the width for 2-D) was det. This h/r is decreased dramatically initially and saturated after 100 hours. The measured values of h/r and normalized values for comparison are well matched with the model.

Evaporation: Firing tests, similar to surface diffusion, were performed with single crystal silicon with a micro-meter scale trenches. However, for this, TiN diffusion barriers coated on the side-wall and bottom of the trenches. Top surface was originally coated with TiN but this layer was polished out by mechanical-chemical polishing. To make substantially similar condition with previous surface diffusion test, the sample was heated to 850° C. and left for 100 hours. The width did not change as much as it had before. These two samples were analyzed for height-to-width ratio. Interestingly, the coating on the side-wall and bottom reduced the geometry loss by evaporation. Since the test setup included flowing a large amount of forming gas to prevent oxidation, it was hard to observe the re-condensation phenomena.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of and “consisting essentially of shall be closed or semi-closed transitional phrases, respectively, as set forth in the United States Patent Office Manual of Patent Examining Procedures, Section 2111.03.

What is claimed:

1. An article, comprising
a substrate material comprising at least one nanostructure formed in at least one surface of the substrate material;
a filler material formed in the at least one nanostructure; and
a first film positioned between the at least one substrate material and the filler material.

2. A method of forming an article, comprising:
providing a substrate material comprising at least one nanostructure formed in at least one surface of the substrate material;
optionally forming a first film on the surface of the at least one nano structure; and
filling the at least one nano structure with at least one filler material.

3. An article comprising:
a substrate material comprising a photonic material and at least one nanostructure formed in at least one surface of the substrate; and
a filler material formed in the at least one nanostructure.

4. An article of claim 1, wherein the substrate material comprises a plurality of nanostructures formed in at least one surface of the substrate material.

5. An article of claim 1, wherein the at least one nanostructure has an average cross-section diameter between about 10 nm and about 1 microns.

6. An article of claim 1, wherein the substrate material is a photonic material.

7. An article of claim 1, wherein the substrate material is photonic material and the nanostructures formed in the surface form a two-dimensional photonic crystal.

8. An article of claim 1, wherein the substrate material comprises tungsten, tantalum, or molybdenum.

9. An article of claim 1, wherein the first film functions as a diffusion barrier between the substrate material and the filler material.

10. An article of claim 1, wherein the first film has an average thickness of less than or about 1000 nm, and about 10 nm, or between about 3 nm and about 8 nm, or between about 5 nm and about 8 nm.

11. An article of claim 1, wherein the filler material has a thermal expansion coefficient within about 10, or about 9, or about 8, or about 7, or about 6, or about 5, or about 4, or about 3, or about 2 orders of magnitude, or is approximately equal to, the thermal expansion coefficient of the substrate material.

12. An article of claim 1, wherein the filler material has selected optical properties.

13. An article of claim 1, further comprises a second film formed on at least a portion of the outside surfaces of the article.

14. A method of claim 2, further comprises polishing the at least one surface thereby forming a substantially uniform surface comprising the filled nano structures.

15. A method of claim 14, further comprising forming a second film on the substantially uniform surface.

16. A thermophotovolatic system comprising an article of claim 1.

17. A method of claim 2, further comprising at least one annealing step.

18. A method of claim 17, wherein the at least one annealing step is conducted on the substrate material prior to formation of the at least one nanostructure.

19. A method of claim 17, wherein the at least one annealing step is conducted on the article following filling the at least one nanostructure with the at least one filler material.

20. An article of claim 1, wherein the first film aids in the adhesion of the substrate material to the filler material.

21. An article of claim 1, wherein the nanostructures are formed as grooves in the at least one surface of the substrate material.
